(19) United States
(12) Patent Application Publication
(10) Pub. No.: US 2021/0001354 A1
(43) Pub. Date: Jan. 7, 2021

(54) RESERVOIR TANK

(71) Applicant: TIGERS POLYMER CORPORATION, Osaka (JP)

(72) Inventors: Shunsuke SAKATA, Hyogo (JP); Eiji TSUGUI, Hyogo (JP)

(21) Appl. No.: 16/907,656

(22) Filed: Jun. 22, 2020

(30) Foreign Application Priority Data
Jul. 1, 2019 (JP) 2019-123092
Jul. 10, 2019 (JP) 2019-128688

(51) Int. Cl. B04C 1/00; F28F 13/00; B01D 19/00

(52) U.S. Cl. CPC B04C 1/00; B01D 19/0057; F28F 13/00

(57) ABSTRACT

A reservoir tank includes: a tank chamber for storing a cooling fluid; a gas-liquid separation chamber provided adjacently below the tank chamber in a vertical direction; a partition wall for partitioning the tank chamber and the gas-liquid separation chamber; an inflow pipe for sending the cooling fluid into the reservoir tank; and a discharge pipe for discharging the cooling fluid from the reservoir tank. The inflow pipe and the discharge pipe are connected to the gas-liquid separation chamber, the gas-liquid separation chamber has a cylindrical outer peripheral wall, the cooling fluid sent in from the inflow pipe to the gas-liquid separation chamber flows along the cylindrical outer peripheral wall in a curved manner so as to rotate around a vertical axis, and is guided to the discharge pipe, the partition wall is provided with a communication hole communicating the tank chamber with the gas-liquid separation chamber, and the communication hole is provided at a position closer to a central axis of the cylindrical outer peripheral wall than to the cylindrical outer peripheral wall when viewed in the vertical direction.

### CROSS-REFERENCE TO RELATED APPLICATION

This application claims priority from Japanese Patent Application No. 2019-123092 filed with the Japan Patent Office on Jul. 1, 2019, and from Japanese Patent Application No. 2019-128688 filed with the Japan Patent Office on Jul. 10, 2019, the entire contents of both of which are hereby incorporated by reference.

### BACKGROUND

### 1. Technical Field

One aspect of the present disclosure relates to a reservoir tank.

### 2. Description of the Related Art

Liquid-cooled cooling systems are used for cooling internal combustion engines, electric elements, electronic boards, and the like. In the liquid-cooled cooling system, heat is collected from a member to be cooled by circulating a cooling fluid, and the member to be cooled is cooled by dissipating heat from a heat radiator. In the liquid-cooled cooling system, a cooling fluid tank, that is, the reservoir tank, may be provided in a cooling fluid circuit for circulating the cooling fluid. The reservoir tank is used to compensate for a decrease in the cooling fluid due to vaporization or the like, and to absorb a volume change of the cooling fluid due to a temperature change. When air bubbles are generated in the cooling fluid, cooling efficiency may decrease. Therefore, the bubbles in the cooling fluid may be separated by the reservoir tank, that is, gas-liquid separation may be performed.

For example, in a technique disclosed in JP-A-2005-248753, rectangular baffle plates are arranged in a reservoir tank body so as to have a windmill shape in a specific direction. JP-A-2005-248753 discloses that according to the reservoir tank, the bubbles can be separated from the cooling fluid without increasing water flow resistance and complicating its structure.

### SUMMARY

A reservoir tank includes: a tank chamber for storing a cooling fluid; a gas-liquid separation chamber provided adjacently below the tank chamber in a vertical direction; a partition wall for partitioning the tank chamber and the gas-liquid separation chamber; an inflow pipe for sending the cooling fluid into the reservoir tank; and a discharge pipe for discharging the cooling fluid from the reservoir tank. The inflow pipe and the discharge pipe are connected to the gas-liquid separation chamber, the gas-liquid separation chamber has a cylindrical outer peripheral wall, the cooling fluid sent in from the inflow pipe to the gas-liquid separation chamber flows along the cylindrical outer peripheral wall in a curved manner so as to rotate around a vertical axis, and is guided to the discharge pipe, the partition wall is provided with a communication hole communicating the tank chamber with the gas-liquid separation chamber, and the communication hole is provided at a position closer to a central axis of the cylindrical outer peripheral wall than to the cylindrical outer peripheral wall when viewed in the vertical direction.

### BRIEF DESCRIPTION OF THE DRAWINGS

FIG. 1 is an exploded perspective view illustrating a structure of a reservoir tank of a first embodiment;

FIG. 2 is a cross-sectional view taken along a line X-X shown in FIG. 1, illustrating the structure of the reservoir tank of the first embodiment;

FIG. 3 is a cross-sectional view taken along a line Y-Y shown in FIG. 2, illustrating the structure of the reservoir tank of the first embodiment;

FIG. 4 is a cross-sectional view taken along the line Y-Y shown in FIG. 2, illustrating an operation of the reservoir tank of the first embodiment;

FIG. 5 is a cross-sectional view illustrating the structure of the reservoir tank of a second embodiment;

FIG. 6 is an exploded perspective view illustrating the structure of the reservoir tank according to a third embodiment;

FIG. 7 is a cross-sectional view taken along a line X-X shown in FIG. 6, illustrating the structure of the reservoir tank of the third embodiment;

FIG. 8 is a cross-sectional view taken along a line Y-Y shown in FIG. 7, illustrating the structure of the reservoir tank of the third embodiment;

FIG. 9 is a cross-sectional view taken along the line Y-Y shown in FIG. 7, illustrating the operation of the reservoir tank of the third embodiment;

FIG. 10 is an exploded perspective view illustrating the structure of the reservoir tank according to a fourth embodiment;

FIG. 11 is a cross-sectional view illustrating the structure of the reservoir tank according to the fourth embodiment;

FIG. 12 is a cross-sectional view taken along a line A-A shown in FIG. 11, illustrating the operation of the reservoir tank of the fourth embodiment;

FIG. 13 is a cross-sectional view taken along the line X-X, illustrating the operation of the reservoir tank of a fifth embodiment, and corresponding to FIGS. 2 and 7;

FIG. 14 is a cross-sectional view taken along the line X-X, illustrating the structure of the reservoir tank of a sixth embodiment, and corresponding to FIGS. 2 and 7; and

FIG. 15 is a cross-sectional view taken along the line A-A, illustrating the structure and the operation of the reservoir tank of the sixth embodiment, and corresponding to FIG. 12.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In recent years, in order to improve performance of a cooling system, there has been a demand for increasing a flow rate of cooling fluid passing through a reservoir tank as disclosed in JP-A-2005-248753. However, it has been found that when the flow rate of the cooling fluid passing through the reservoir tank increases in the reservoir tank as disclosed in JP-A-2005-248753, the cooling fluid flowing into a tank body tends to be undulating and turbulent, and thus air in the tank is easily entrained in the cooling fluid, so that it is difficult to obtain an expected level of gas-liquid separation effect.

One object of the present disclosure is to provide a reservoir tank that can perform a gas-liquid separation while controlling turbulent surface of the liquid inside the tank body.

As a result of intensive studies, the inventors have found that the above object is achieved by partitioning, with a partition wall, the inside of the reservoir tank into an upper tank chamber and a lower portion where a main flow of the cooling fluid flows, by performing the gas liquid separation using a centrifugal force in the portion where the main flow flows, and by providing a communication hole penetrating the partition wall at an area where the air bubbles are easily collected. Thus, the technology of the present disclosure has been completed.

A reservoir tank according to an aspect of the present disclosure includes: a tank chamber for storing a cooling fluid; a gas-liquid separation chamber provided adjacently below the tank chamber in a vertical direction; a partition wall for partitioning the tank chamber and the gas-liquid separation chamber; an inflow pipe for sending the cooling fluid into the reservoir tank; and a discharge pipe for discharging the cooling fluid from the reservoir tank. The inflow pipe and the discharge pipe are connected to the gas-liquid separation chamber, the gas-liquid separation chamber has a cylindrical outer peripheral wall, the cooling fluid sent in from the inflow pipe to the gas-liquid separation chamber flows along the cylindrical outer peripheral wall in a curved manner so as to rotate around a vertical axis, and is guided to the discharge pipe, the partition wall is provided with a communication hole communicating the tank chamber with the gas-liquid separation chamber, and the communication hole is provided at a position closer to a central axis of the cylindrical outer peripheral wall than to the cylindrical outer peripheral wall when viewed in the vertical direction (first aspect).

A reservoir tank according to another aspect of the present disclosure includes: a tank chamber for storing a cooling fluid; a curved channel provided adjacently below the tank chamber in a vertical direction; a partition wall for partitioning the tank chamber and the curved channel; an inflow pipe for sending the cooling fluid into the reservoir tank; and a discharge pipe for discharging the cooling fluid from the reservoir tank. The inflow pipe and the discharge pipe are connected to the curved channel, the curved channel has a cylindrical outer peripheral wall, the cooling fluid sent in from the inflow pipe to the curved channel flows along the cylindrical outer peripheral wall in a curved manner so as to rotate around a vertical axis, and is guided to the discharge pipe, the partition wall is provided with a communication hole communicating the tank chamber with the curved channel, and the communication hole is provided on a radially inner peripheral side of a curve of the curved channel when viewed in the vertical direction (second aspect).

In the reservoir tank according to the first aspect or the second aspect, the partition wall is preferably provided to have a conical surface shape that goes vertically upward as it goes from an outer peripheral portion of the partition wall to the communication hole (third aspect).

In the reservoir tank according to the first aspect, a bottom surface of the gas-liquid separation chamber, which is located below in the vertical direction, is preferably provided with a conical surface that goes vertically upward as it goes from the cylindrical outer peripheral wall to the central axis of the cylindrical outer peripheral wall (fourth aspect).

In the reservoir tank according to the second aspect, a bottom surface of the curved channel, which is located below in the vertical direction, is preferably provided with a conical surface that goes vertically upward as it goes to the radially inner peripheral side of the curve of the curved channel (fifth aspect).

In the reservoir tank according to the first aspect, the communication hole is preferably provided to be shifted downstream in a direction along a flow of the cooling fluid in the gas-liquid separation chamber (sixth aspect).

In the reservoir tank according to the second aspect, the communication hole is preferably provided to be shifted downstream in a direction along a flow of the cooling fluid in the curved channel (seventh aspect).

The reservoir tank according to any one of the first to seventh aspects preferably further includes a suction hole that communicates the discharge pipe with the tank chamber (eighth aspect).

With the reservoir tank according to the first aspect or the second aspect, it is possible to obtain an effect that the gas-liquid separation can be performed while controlling the turbulent surface of the liquid inside the tank body.

Further, with the reservoir tank according to the third aspect, the fourth aspect, or the fifth aspect, efficiency of the gas-liquid separation by the gas-liquid separation chamber is further increased. Therefore, the gas-liquid separation effect can be further enhanced.

Further, with the reservoir tank according to the sixth aspect or the seventh aspect, the gas-liquid separation effect can be enhanced while better controlling the turbulent liquid surface.

Furthermore, with the reservoir tank according to the eighth aspect, it is possible to circulate the cooling fluid from which the bubbles have been removed to the discharge pipe from the suction hole while feeding the cooling fluid containing the bubbles into the tank chamber. Therefore, the gas-liquid separation effect can be further enhanced.

Hereinafter, embodiments of the present disclosure will be described with reference to the drawings, taking the reservoir tank provided in a liquid-cooled cooling system for an internal combustion engine of an automobile as an example. The technology of the present disclosure is not limited to individual embodiments described below, but may also be implemented as modified embodiments below. Applications of the liquid cooling type cooling system are not limited to the internal combustion engine, but may be applications for cooling an electric element such as a power element and an inverter, and an electric component such as an electronic circuit board.

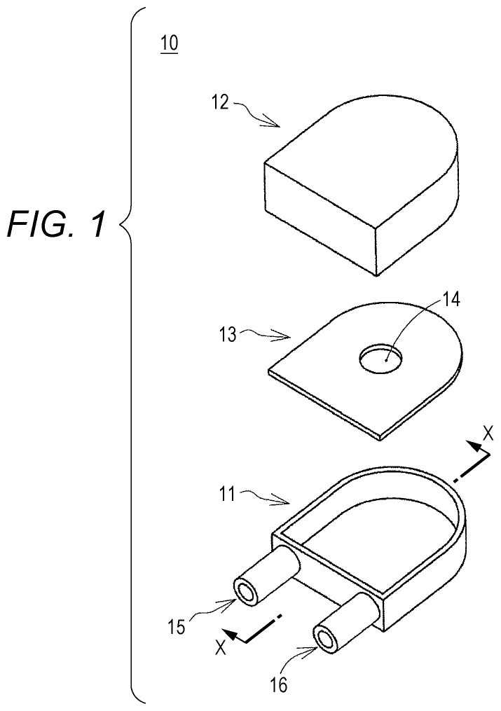

FIGS. 1, 2 and 3 illustrate a structure of a reservoir tank 10 of a first embodiment. FIG. 1 illustrates main members of the reservoir tank 10 in an exploded state using a perspective view. The reservoir tank 10 is configured to include a hollow tank, and an inflow pipe 15 and a discharge pipe 16 connected to the tank. The reservoir tank 10 used in a cooling fluid circuit of the liquid-cooled cooling system is disposed and connected in the cooling fluid circuit of the liquid-cooled cooling system so that the cooling fluid flows from the inflow pipe 15 into the hollow tank, and the cooling fluid flows out of the hollow tank through the discharge pipe 16.

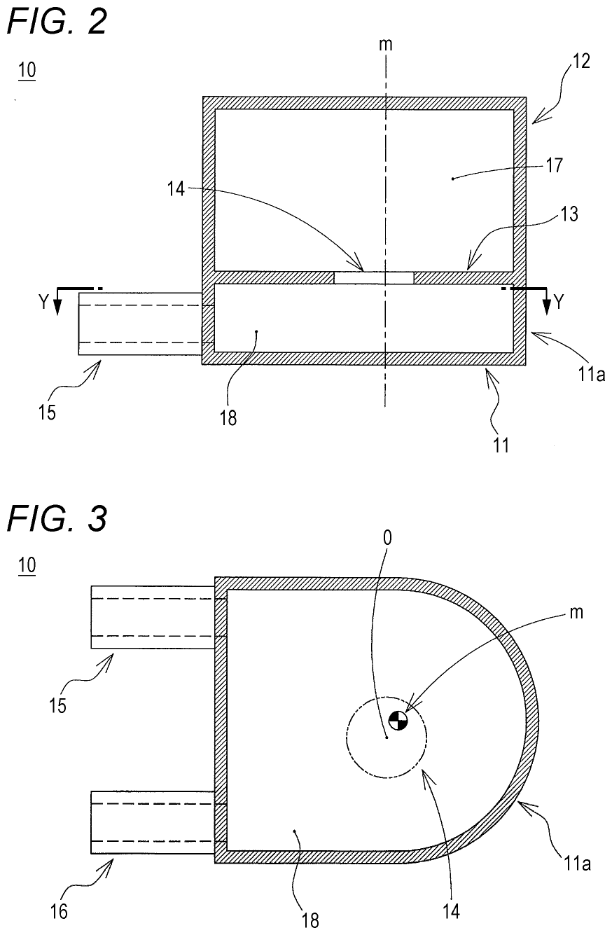

FIG. 2 is a cross-sectional view illustrating a cross-section of the reservoir tank 10 taken along a vertical plane including a line X-X (X-X axis) in FIG. 1. An upper side in FIG. 2 corresponds to the upper side in the vertical direction. FIG. 3 is a cross-sectional view illustrating a cross-section of the reservoir tank 10 taken along a horizontal plane including a line Y-Y (Y-Y axis) in FIG. 2. In the first embodiment, the reservoir tank 10 is formed by integrating a lower case 11, an upper case 12, and a partition wall 13 together. The lower case 11 and the upper case 12 are integrated to form the hollow tank. Such a tank is partitioned by the partition wall 13. In the first embodiment, the partition wall 13 is formed in a flat plate shape. The partition wall 13 extends substantially horizontally and partitions the hollow tank.

An upper room (space) of the hollow tank partitioned by the partition wall 13 is referred to as a tank chamber 17. The cooling fluid is stored in the tank chamber 17. The tank chamber 17 is surrounded by the upper case 12 and the partition wall 13. A lower room (space) of the hollow tank partitioned by the partition wall 13 is referred to as a gas-liquid separation chamber 18. The gas-liquid separation chamber 18 is surrounded by the lower case 11 and the partition wall 13. The gas-liquid separation chamber 18 is provided below the tank chamber 17 in the vertical direction so as to be adjacent to the tank chamber 17 through the partition wall 13.

When the reservoir tank 10 is used, the gas-liquid separation chamber 18 is substantially filled with the cooling fluid. When it is used, most of the space in the tank chamber 17 is filled with the cooling fluid, and the air is stored in an upper portion of the tank chamber 17. That is, the partition wall 13 is configured such that the whole of the partition wall 13 is immersed in the cooling fluid when used. Although not essential, the lower case 11, the upper case 12, and the partition wall 13 are preferably joined to each other so that the cooling fluid does not easily flow back and forth between the outer peripheral portion of the partition wall 13 and the upper case 12 or the lower case 11.

That is, the reservoir tank 10 provided in the cooling fluid circuit of the liquid-cooled cooling system includes the tank chamber 17 for storing the cooling fluid, the gas-liquid separation chamber 18 provided adjacently below the tank chamber 17 in the vertical direction, the partition wall 13 for partitioning the tank chamber 17 and the gas-liquid separation chamber 18, the inflow pipe 15 for feeding the cooling fluid into the reservoir tank 10, and the discharge pipe 16 for discharging the cooling fluid from the reservoir tank 10. The lower case 11, the upper case 12, the partition wall 13, and the like are assembled so that the structure of the reservoir tank 10 can be realized.

As long as the tank chamber 17 and the gas-liquid separation chamber 18 of the reservoir tank 10 can be formed, a manner of dividing the members for realizing such a structure is not particularly limited. In the first embodiment, the reservoir tank 10 is divided into three members of the lower case 11, the upper case 12, and the partition wall 13. By assembling the members, the structure of the reservoir tank 10 having the tank chamber 17, the gas-liquid separation chamber 18 and the like is realized. In this regard, such a structure may be realized by other members. For example, the tank chamber 17 and the gas-liquid separation chamber 18 may be divided by a vertical plane to form the constituent members, which may be assembled to realize the structure of the reservoir tank 10 having the tank chamber 17, the gas-liquid separation chamber 18, and the like.

The inflow pipe 15 and the discharge pipe 16 are connected to the gas-liquid separation chamber 18. That is, in the reservoir tank 10, the cooling fluid flows into the gas-liquid separation chamber 18 from the inflow pipe 15 and flows out of the gas-liquid separation chamber 18 through the discharge pipe 16. As in the first embodiment, the inflow pipe 15 and the discharge pipe 16 are preferably formed integrally with the lower case 11. Or, the inflow pipe 15 and the discharge pipe 16 may be provided at positions separated from the gas-liquid separation chamber 18. Even in this case, the inflow pipe 15 and the discharge pipe 16 can be connected to the gas-liquid separation chamber 18 by forming a pipe line or a guide plate inside or on an outer periphery of the reservoir tank 10. Even in this case, the reservoir tank 10 can be configured such that the cooling fluid flows into the gas-liquid separation chamber 18 from the inflow pipe 15 and flows out of the gas-liquid separation chamber 18 through the discharge pipe 16. As long as the inflow pipe 15, the discharge pipe 16 and the gas-liquid separation chamber 18 are connected to each other such that the main flow of the cooling fluid substantially flows from the inflow pipe 15 through the gas-liquid separation chamber 18 to the discharge pipe 16, a part of the cooling fluid may flow to other parts.

The gas-liquid separation chamber 18 has a cylindrical outer peripheral wall 11a. The cylindrical outer peripheral wall 11a is formed such that a center line of cylinder extends in a substantially vertical direction. The cylindrical outer peripheral wall 11a does not need to be strictly cylindrical. The outer peripheral wall 11a may be a part of a cylindrical surface, a part of a conical surface, or a part of a torus surface. A radius of curvature of the outer peripheral wall 11a in a circumferential direction may be constant or may change.

The gas-liquid separation chamber 18 is configured such that the cooling fluid fed from the inflow pipe 15 into the gas-liquid separation chamber 18 flows along the cylindrical outer peripheral wall 11a in a curved manner so as to rotate around a vertical axis, and is guided to the discharge pipe 16. In the first embodiment, as illustrated in the cross-sectional views of FIGS. 2 and 3, the gas-liquid separation chamber 18 is formed as a flat chamber (space) extending in a substantially horizontal direction. As illustrated in FIG. 3, the gas-liquid separation chamber 18 is surrounded by a substantially D-shaped outer peripheral wall 11a when viewed in the vertical direction. In the first embodiment, the cylindrical outer peripheral wall 11a surrounds a right half of the gas-liquid separation chamber 18 in FIG. 3. In the gas-liquid separation chamber 18, the cooling fluid flows curved in an arc shape to be along a substantially horizontal plane.

Although not essential, in the first embodiment, the inflow pipe 15 is substantially horizontally connected to the separation chamber 18 so that a jet of the cooling fluid from the inflow pipe 15 flows in contact with an inner surface of the cylindrical outer peripheral wall 11a. Although not essential, in the first embodiment, the discharge pipe 16 is substantially horizontally connected to the separation chamber 18 so that the cooling fluid flowing in contact with the inner surface of the cylindrical outer peripheral wall 11a directly flows out of the discharge pipe 16.

As long as the cooling fluid fed from the inflow pipe 15 into the gas-liquid separation chamber 18 flows along the cylindrical outer peripheral wall 11a in a curved manner so as to rotate around the vertical axis and is guided to the discharge pipe 16, a specific shape of the gas-liquid separation chamber 18 and a specific arrangement of the inflow pipe 15 and the discharge pipe 16 are not particularly limited. For example, a cross-sectional shape of the gas-liquid separation chamber 18 when viewed in the vertical direction may be circular. In the first embodiment, a mode has been described, in which the cooling fluid flowing in from the inflow pipe 15 changes its direction by about 180 degrees and flows out of the discharge pipe 16. In this regard, a change in angle of flow of the cooling fluid in the gas-liquid separation chamber 18 as viewed in the vertical direction is preferably 90 degrees or more, and particularly preferably 180 degrees or more.

The partition wall 13 is provided with a communication hole 14 that communicates the tank chamber 17 with the gas-liquid separation chamber 18. That is, between the tank chamber 17 and the gas-liquid separation chamber 18, the cooling fluid, the bubbles, and the air can flow up and down through the communication hole 14.

As illustrated in FIG. 3, the communication hole 14 is provided at a position closer to a central axis m of the cylindrical outer peripheral wall 11a than to the cylindrical outer peripheral wall 11a when viewed in the vertical direction. In FIG. 3, the central axis m of the cylindrical outer peripheral wall 11a is indicated by a center of gravity mark. It is preferable that the communication hole 14 includes the central axis m of the cylindrical outer peripheral wall 11a when viewed in the vertical direction. However, the communication hole 14 may be provided such that the central axis m is outside the communication hole 14 when viewed in the vertical direction. Here, when a rotationally symmetrical cylinder including the cylindrical outer peripheral wall 11a is imagined, the central axis m of the cylindrical outer peripheral wall 11a means a centroid of cross-section of the cylinder. When the cylindrical outer peripheral wall 11a is substantially a part of the cylinder, the central axis of the cylinder corresponds to the central axis m.

The communication hole 14 is preferably provided at the position closer to the central axis m of the cylindrical outer peripheral wall 11a than to the cylindrical outer peripheral wall 11a when viewed in the vertical direction, that is, the communication hole 14 is preferably not open near the cylindrical outer peripheral wall 11a while it is open near the central axis m of the cylindrical outer peripheral wall 11a. That is, the reservoir tank 10 is preferably configured such that the partition wall 13 partitions the gas-liquid separation chamber 18 and the tank chamber 17 in a portion near the cylindrical outer peripheral wall 11a, and the partition wall 13 is provided with the communication hole 14 in a portion near the central axis m of the cylindrical outer peripheral wall 11a apart from the cylindrical outer peripheral wall 11a, so that the cooling fluid and the bubbles can flow back and forth between the gas-liquid separation chamber 18 and the tank chamber 17. The communication hole 14 may be a single hole or a set of a plurality of holes.

The communication hole 14 is preferably provided in the gas-liquid separation chamber 18 so as to be shifted downstream in the direction along the flow of the cooling fluid. The cooling fluid flows into the gas-liquid separation chamber 18 shown in FIG. 3 from the inflow pipe 15 connected to an upper left side of the gas-liquid separation chamber 18. Therefore, a connection portion with the inflow pipe 15 in the gas-liquid separation chamber 18 is an upstream portion of the gas-liquid separation chamber 18. Further, the cooling fluid flows out of the discharge pipe 16 connected to a lower left side of the gas-liquid separation chamber 18. Therefore, a connection portion with the discharge pipe 16 in the gas-liquid separation chamber 18 is a downstream portion of the gas-liquid separation chamber 18. Then, a portion of the gas-liquid separation chamber 18 in which the cooling fluid flows along the cylindrical outer peripheral wall 11a is a midstream portion of the gas-liquid separation chamber 18. When inside of the gas-liquid separation chamber 18 is divided into the upstream portion, the midstream portion, and the downstream portion that are continuous as described above, the communication hole 14 is preferably provided to be shifted downstream in the direction along the flow of the cooling fluid. That is, the communication holes 14 are preferably provided unevenly so that more communication holes 14 are opened midstream than upstream and more communication holes 14 are opened downstream than midstream. Although not essential, in the first embodiment, as illustrated in FIG. 3, a center O of the circular communication hole 14 is disposed on a lower left side of the central axis m of the cylindrical outer peripheral wall 11a. Thus, the communication hole 14 is provided to be shifted downstream in the direction along the flow of the cooling fluid in the gas-liquid separation chamber 18.

In the first embodiment, a material forming the reservoir tank 10 and a method for manufacturing the reservoir tank 10 are not particularly limited. The reservoir tank 10 can be manufactured by a known material and a known manufacturing method. Typically, the reservoir tank 10 is formed using a thermoplastic resin such as a polyamide resin as a main material. The material, reinforcing structure, and the like of the reservoir tank 10 are determined depending on the type, temperature, pressure, and the like of the cooling fluid to be used. Typically, the reservoir tank 10 can be manufactured by respectively forming members corresponding to the lower case 11, the upper case 12, and the partition wall 13 by injection molding, and by integrating the members by vibration welding, hot plate welding or the like.

An operation and effect of the reservoir tank 10 of the first embodiment will be described. With the reservoir tank 10 of the first embodiment, the gas-liquid separation can be performed while controlling the turbulent surface of the liquid in the tank body.

In the reservoir tank 10 of the first embodiment, as illustrated in FIG. 2, the tank chamber 17 for storing the cooling fluid, and the gas-liquid separation chamber 18 provided adjacently below the tank chamber 17 in the vertical direction are partitioned by the partition wall 13. The inflow pipe 15 and the discharge pipe 16 are connected to the gas-liquid separation chamber 18. Thus, the cooling fluid flowing in from the inflow pipe 15 flows through the gas-liquid separation chamber 18 to the discharge pipe 16. Thus, in the reservoir tank 10, a strong flow from the inflow pipe 15 hardly flows into the tank chamber 17. Therefore, even if the flow rate of the cooling fluid flowing in from the inflow pipe 15 increases, it is possible to control the turbulent surface of the liquid in the tank chamber 17 in which the cooling fluid and the air are stored. If the turbulent liquid surface is controlled, it is difficult for the cooling fluid to entrain the bubbles in the tank chamber 17, so that gas-liquid separation performance is also improved.

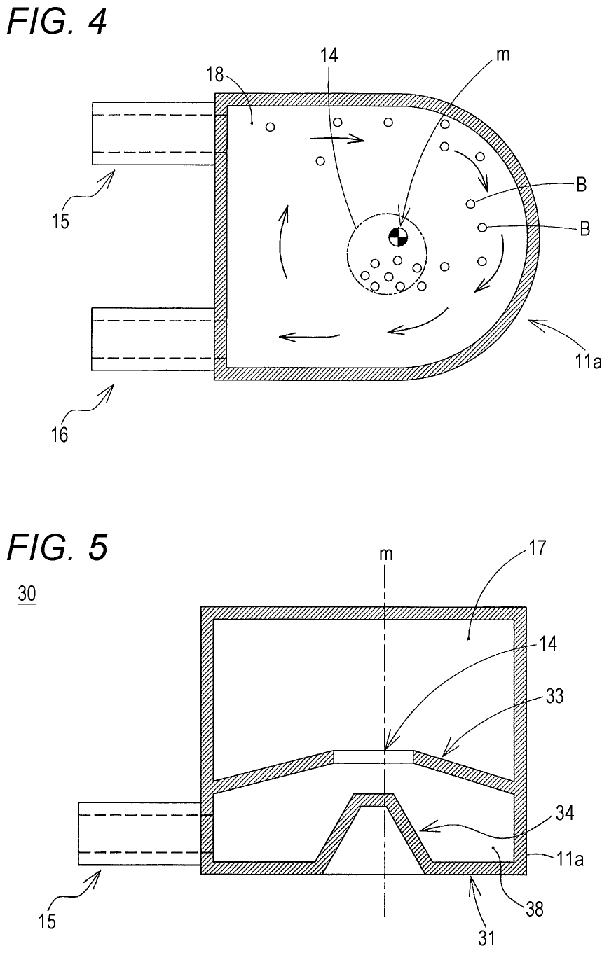

As illustrated in FIG. 4, in the reservoir tank 10 of the first embodiment, the gas-liquid separation chamber 18 has the cylindrical outer peripheral wall 11a. The cooling fluid fed from the inflow pipe 15 to the gas-liquid separation chamber 18 flows along the cylindrical outer peripheral wall 11a in a curved manner so as to rotate around the vertical axis, and is guided to the discharge pipe 16. The partition wall 13 is provided with the communication hole 14 that connects the tank chamber 17 and the gas-liquid separation chamber 18. The communication hole 14 is provided at the position closer to the central axis m of the cylindrical outer peripheral wall 11a than to the cylindrical outer peripheral wall 11a when viewed in the vertical direction. With this structure, in the gas-liquid separation chamber 18, the cooling fluid flows along the cylindrical outer peripheral wall 11a in a curved manner so as to rotate around the vertical axis, flowing along a substantially horizontal plane. Due to this curved flow, the centrifugal force acts on the cooling fluid.

When the centrifugal force acts on the cooling fluid containing the bubbles, bubbles B, B tend to collect in a radially inner portion of the cylindrical outer peripheral wall 11a. On the other hand, the cooling fluid that does not contain the bubbles B, B so much tends to collect in a radially outer portion of the cylindrical outer peripheral wall 11a. That is, in the flow of the cooling fluid along the cylindrical outer peripheral wall 11a in the gas-liquid separation chamber 18, the bubbles B, B increase at the portion near the central axis m of the cylindrical outer peripheral wall 11a as it flows downstream, while the bubbles B, B decrease in a portion adjacent to the cylindrical outer peripheral wall 11a.

The communication hole 14 in the partition wall 13 is provided at the position closer to the central axis m of the cylindrical outer peripheral wall 11a than to the cylindrical outer peripheral wall 11a when viewed in the vertical direction. Therefore, the cooling fluid containing the bubbles B, B collected at the portion near the central axis m of the cylindrical outer peripheral wall 11a by the centrifugal force is guided to the tank chamber 17 through the communication hole 14, and is further gas-liquid separated by gravity or the like inside the tank chamber 17.

In the gas-liquid separation chamber 18, the cooling fluid with reduced bubbles B, B flows in the portion adjacent to the cylindrical outer peripheral wall 11a, and is discharged from the discharge pipe 16.

That is, in the reservoir tank 10 of the first embodiment, the bubbles B, B in the cooling fluid are collected by the gas-liquid separation chamber 18 having a function of separating gas and liquid by the centrifugal force. Thus, the cooling fluid with many bubbles flows from the communication hole 14 to the tank chamber 17, and the bubbles are separated from the cooling fluid in the tank chamber 17. On the other hand, the cooling fluid with reduced bubbles is discharged outwardly from the discharge pipe 16. Therefore, the reservoir tank 10 has a high gas-liquid separation efficiency.

Although not essential, from the viewpoint of enhancing the gas-liquid separation effect while controlling the turbulent surface of the liquid inside the tank chamber 17, an opening area of the communication hole 14 is preferably 1/50 or more and ½ or less of a cross-sectional area of the gas-liquid separation chamber 18 when viewed in the vertical direction, and more preferably 1/30 or more and ⅓ or less. Further, from the same viewpoint, assuming that the radius of the cylindrical outer peripheral wall 11a is R, a peripheral edge of the communication hole 14 is preferably separated by about R/5 to R/2 from a peripheral edge of the gas-liquid separation chamber 18 (particularly, the cylindrical outer peripheral wall 11a) when viewed in the vertical direction.

Although not essential, from the viewpoint of increasing the gas-liquid separation efficiency, as the reservoir tank 10 of the first embodiment, the communication hole 14 is preferably provided to be shifted downstream in the direction along the flow of the cooling fluid in the gas-liquid separation chamber 18. The centrifugal force acts on the cooling fluid as a result of the curved flow along the cylindrical outer peripheral wall 11a in the gas-liquid separation chamber 18. Thus, the bubbles B, B are collected radially inward of the cylinder as the flow goes downstream, and the bubbles radially outward of the cylinder decrease. Therefore, the cooling fluid containing more bubbles B, B can be guided to the tank chamber 17 through the communication hole 14 provided near the central axis m of the cylindrical outer peripheral wall 11a.

The aspects of the present disclosure are not limited to the above embodiments, but can be implemented with various modifications. Hereinafter, other embodiments of the present disclosure will be described. In the following description, portions different from the above embodiment will be mainly described, and the same portions will be denoted by the same reference numerals and detailed description thereof will be omitted. Further, the embodiments can be implemented by combining some of them or replacing some of them.

FIG. 5 illustrates a reservoir tank 30 according to the second embodiment. FIG. 5 is a cross-sectional view corresponding to FIG. 2 in the first embodiment. In the reservoir tank 30 of the second embodiment, shapes of a partition wall 33 and a bottom surface 31 of the tank are different from those of the reservoir tank 10 of the first embodiment. On the other hand, other structures of the reservoir tank 30 are the same as those of the reservoir tank 10 of the first embodiment.

In the reservoir tank 30 of the second embodiment, the partition wall 33 is provided to have a conical surface shape that goes vertically upward as it goes to the communication hole 14 from the outer peripheral portion of the partition wall 33.

With the partition wall 33 having such a structure, in the gas-liquid separation chamber 38, the air bubbles collected in a central portion of the gas-liquid separation chamber 38 are guided by the partition wall 33 having a conical surface shape, and easily flow to the upper tank chamber 17. Thus, the gas-liquid separation effect can be enhanced.

In the reservoir tank 30 of the second embodiment, the bottom surface 31 located vertically below the gas-liquid separation chamber 38 is provided with a conical surface 34 going vertically upward as it goes to the central axis m of the cylindrical outer peripheral wall 11a from the cylindrical outer peripheral wall 11a. The conical surface 34 is preferably provided below the communication hole 14 so as to coincide with the communication hole 14 when viewed in the vertical direction.

With such a structure, in the gas-liquid separation chamber 38, the bubbles that are about to collect in the central portion of the gas-liquid separation chamber 38 by action of the centrifugal force are guided upward by the conical surface 34, and easily flow to the upper tank chamber 17. Thus, the gas-liquid separation effect can be enhanced.

The reservoir tank 30 of the second embodiment has both of the conical partition wall 33 and the conical surface 34 of the bottom surface 31. This stabilizes the curved flow of the cooling fluid along the cylindrical outer peripheral wall 11a. Therefore, a fast flow near the cylindrical outer peripheral wall 11a is suppressed from reaching near the communication hole 14. As a result, an effect of controlling the turbulent surface of the liquid in the tank chamber 17 can also be enhanced.

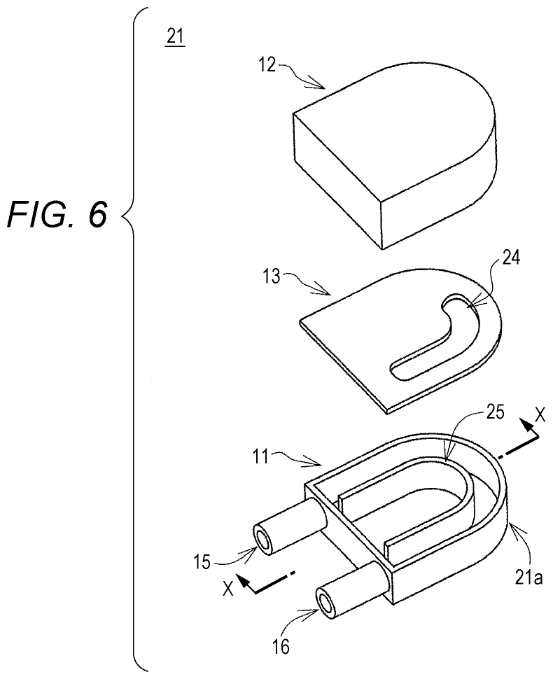

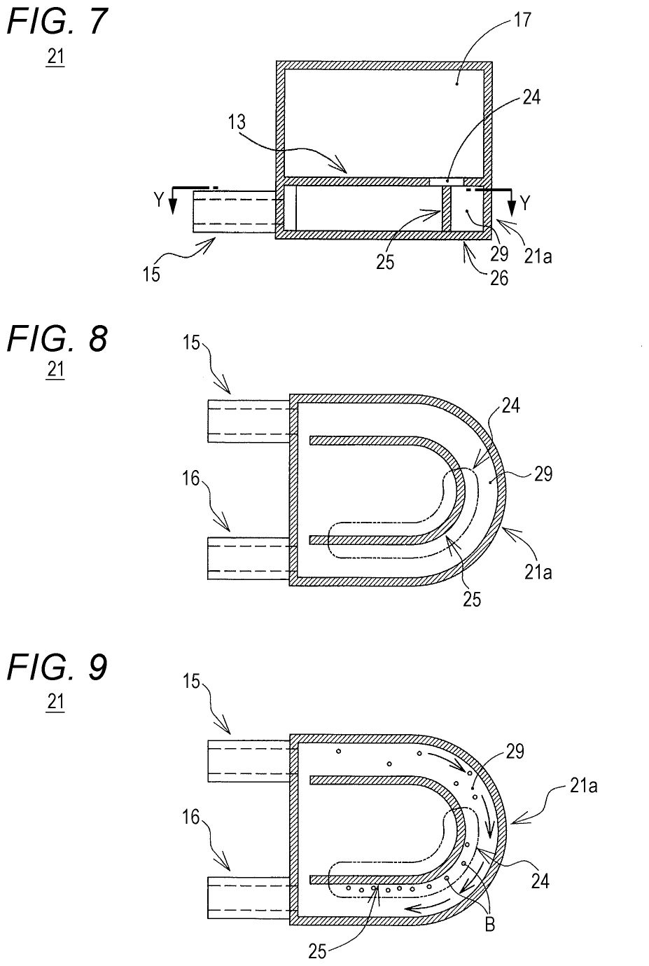

FIGS. 6, 7, 8 and 9 illustrate a reservoir tank 21 according to a third embodiment. The structure of the reservoir tank 21 is illustrated in an exploded perspective view of FIG. 6, a cross-sectional view taken along a line X-X (see FIG. 6) of FIG. 7, and a cross-sectional view taken along a line Y-Y (see FIG. 7) of FIG. 8. FIG. 9 illustrates a gas-liquid separation operation of the reservoir tank 21.

The reservoir tank 21 of the third embodiment has a curved channel 29 as compared with the reservoir tank 10 of the first embodiment. That is, the reservoir tank 21 has a structure, in which the gas-liquid separation chamber 18 in the structure of the reservoir tank 10 of the first embodiment is replaced with the curved channel 29. Other structures of the reservoir tank 21 are the same as those of the reservoir tank 10 of the first embodiment.

The reservoir tank 21 of the third embodiment includes the tank chamber 17 for storing the cooling fluid and the air, the curved channel 29 provided adjacently below the tank chamber 17 in the vertical direction, the partition wall 13 for partitioning the tank chamber 17 and the curved channel 29, the inflow pipe 15 for feeding the cooling fluid into the reservoir tank 21, and the discharge pipe 16 for discharging the cooling fluid from the reservoir tank 21. The inflow pipe 15 and the discharge pipe 16 are connected by the curved channel 29.

The curved channel 29 has a cylindrical outer peripheral wall 21a. The cooling fluid fed from the inflow pipe 15 into the curved channel 29 flows along the cylindrical outer peripheral wall 21a in a curved manner so as to rotate around the vertical axis, and is guided to the discharge pipe 16. In the third embodiment, the curved channel 29 is formed as a substantially horseshoe-shaped curved pipe line, surrounded by the cylindrical outer peripheral wall 21a, an inner peripheral wall 25, a tank bottom surface 26, and the partition wall 13. The curved channel 29 may have a straight tubular portion as in the third embodiment. The reservoir tank 21 is configured such that a radially inner portion of the inner peripheral wall 25 is also filled with the cooling fluid.

The partition wall 13 is provided with a communication hole 24 that communicates the tank chamber 17 with the curved channel 29. The communication hole 24 is provided on the radially inner peripheral side of the curve of the curved channel 29 when viewed in the vertical direction. That is, the communication hole 24 is provided to communicate the tank chamber 17 with the curved channel 29 not on an outer peripheral side but on the inner peripheral side of the curved channel 29.

The communication hole 24 may be provided in a long hole shape as in the third embodiment. The communication hole 24 may be circular or elliptical. Further, when a space is also provided in a portion inside the inner peripheral wall 25 as in the third embodiment, the communication hole 24 is preferably provided to communicate the radially inner portion of the inner peripheral wall 25 with the tank chamber 17.

Also in the reservoir tank 21 of the third embodiment, the cooling fluid fed from the inflow pipe 15 to the curved channel 29 flows along the cylindrical outer peripheral wall 21a in a curved manner so as to rotate around the vertical axis, and is guided to the discharge pipe 16. Thus, the centrifugal force acts on the cooling fluid containing the bubbles. As a result, the bubbles B, B tend to collect in a direction toward the central axis of the cylindrical outer peripheral wall 21a (that is, inside the curve) in the curved channel 29. On the other hand, in a direction away from the central axis of the cylindrical outer peripheral wall 21a (that is, outside the curve), the cooling fluid containing few bubbles B, B tends to collect (see FIG. 9). Since the communication hole 24 is provided on the radially inner peripheral side of the curve of the curved channel 29 when viewed in the vertical direction, the cooling fluid with many bubbles is guided to the tank chamber 17 through the communication hole 24. Then, the bubbles are separated from the cooling fluid inside the tank chamber 17. Therefore, also according to the third embodiment, like the reservoir tank 10 of the first embodiment, the gas-liquid separation can be performed while controlling the turbulent surface of the liquid inside the tank body.

From the viewpoint of increasing the gas-liquid separation efficiency and of enhancing the effect of controlling the turbulent surface of the liquid in the tank body, also in the reservoir tank 21 of the third embodiment, like the partition wall 33 of the reservoir tank 30 of the second embodiment, the partition wall 13 is preferably provided to have a conical surface shape that goes vertically upward as it goes from the outer peripheral portion of the partition wall 13 to the communication hole 24.

Further, from the viewpoint of increasing the gas-liquid separation efficiency and of enhancing the effect of controlling the turbulent surface of the liquid in the tank body, also in the reservoir tank 21 of the third embodiment, like the conical surface 34 of the bottom surface 31 of the reservoir tank 30 of the second embodiment, it is preferable that the tank bottom surface 26, which is located vertically below the curved channel 29, is preferably provided with the conical surface that goes vertically upward as it goes to the radially inner peripheral side of the curve of the curved channel 29.

Furthermore, from the viewpoint of increasing the gas-liquid separation efficiency and of enhancing the effect of controlling the turbulent surface of the liquid in the tank body, also in the reservoir tank 21 of the third embodiment, like the reservoir tank 10 of the first embodiment, the communication hole 24 is preferably provided to be shifted downstream in the direction along the flow of the cooling fluid in the curved channel 29.

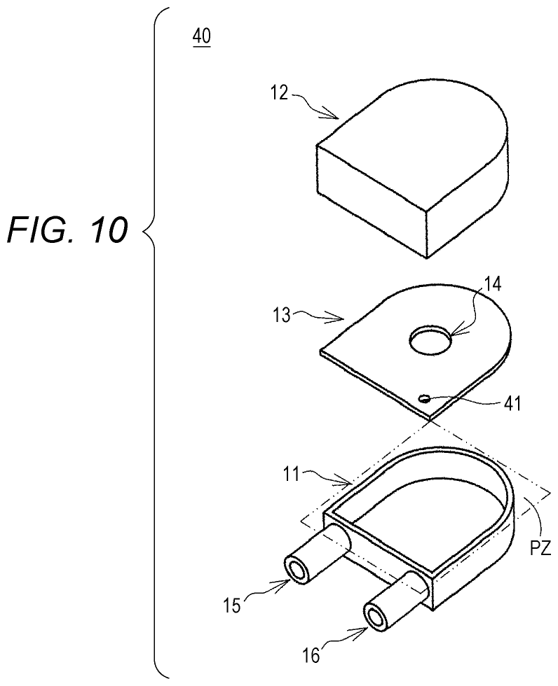

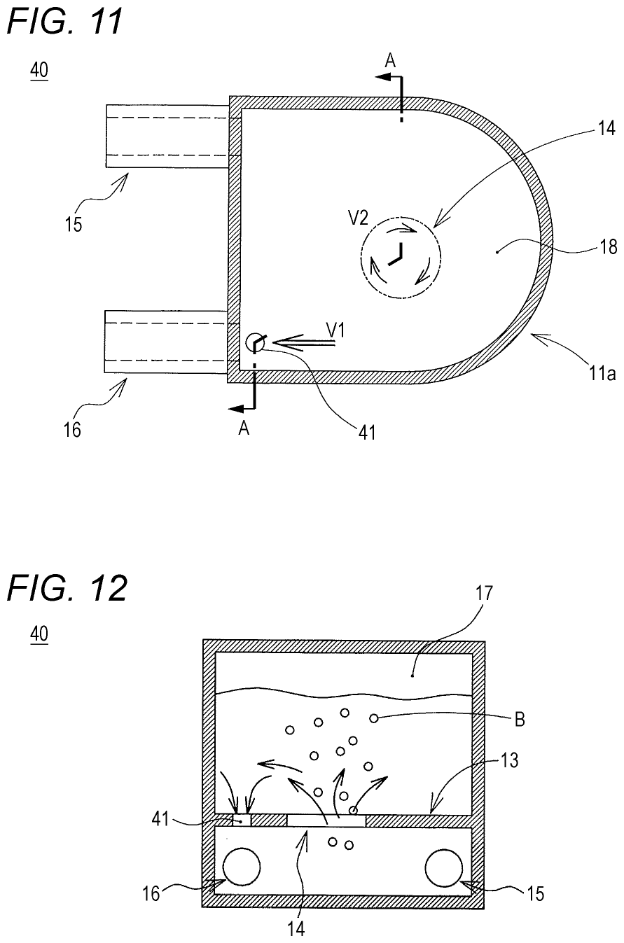

FIGS. 10, 11 and 12 illustrate a reservoir tank 40 of a fourth embodiment. The structure of the reservoir tank 40 is illustrated in an exploded perspective view of FIG. 10 and a cross-sectional view taken along a PZ plane (see FIG. 10) of FIG. 11. A cross-sectional view taken along a line A-A (see FIG. 11) of FIG. 12 illustrates a secondary flow of the cooling fluid.

The reservoir tank 40 of the fourth embodiment further includes a suction hole 41 as compared with the reservoir tank 10 of the first embodiment. The suction hole 41 communicates the discharge pipe 16 with the tank chamber 17. Other structures of the reservoir tank 40 are the same as those of the reservoir tank 10 of the first embodiment.

That is, in the reservoir tank 40 of the fourth embodiment, the communication hole 14 provided in the same manner as the reservoir tank 10 of the first embodiment, and the suction hole 41 that communicates the vicinity of the discharge pipe 16 with the tank chamber 17 are both provided in the partition wall 13.

Here, as illustrated in FIG. 11, in the reservoir tank 40 of the fourth embodiment, the cooling fluid flowing in from the inflow pipe 15 flows in a curved manner along the cylindrical outer peripheral wall 11a, and flows out of the discharge pipe 16. Therefore, near the discharge pipe 16 where the suction hole 41 is provided, a flow rate V1 of the cooling fluid flowing in the gas-liquid separation chamber 18 is fast. On the other hand, in a portion of the gas-liquid separation chamber 18 where the communication hole 14 is provided, the cooling fluid flows weakly in a swirling manner. Thus, in this portion, a flow rate V2 of the cooling fluid flowing in the gas-liquid separation chamber 18 is slow. Therefore, in the gas-liquid separation chamber 18, a flow faster than that near the communication hole 14 exists near the suction hole 41 (that is, V1>V2).

When there is such a flow rate difference, the pressure at the suction hole 41 is lower than the pressure at the communication hole 14 according to so-called Venturi's law. Therefore, as illustrated in FIG. 12, the flow of the cooling fluid that flows from the communication hole 14 to the tank chamber 17 and is sucked from the suction hole 41 to the discharge pipe 16 is caused secondarily. Due to this secondary flow, the cooling fluid containing many bubbles collected near the communication hole 14 flows into the tank chamber 17. Then, the bubbles are separated from the cooling fluid in the tank chamber 17. The cooling fluid with reduced bubbles is discharged through the suction hole 41 to the discharge pipe 16. Therefore, in the reservoir tank 40 having such a structure, it is possible to feed the cooling fluid containing the bubbles into the tank chamber 17, while circulating the cooling fluid, from which the bubbles have been removed, through the suction hole 41. Therefore, the gas-liquid separation performance is particularly improved.

The suction hole 41 is not limited to a through-hole provided in the plate-shaped partition wall 13. As long as the tank chamber 17 and the discharge pipe 16 can be communicated to each other, the suction hole 41 may be formed in a pipe line shape. Further, the suction hole 41 does not need to be directly connected to the discharge pipe 16.

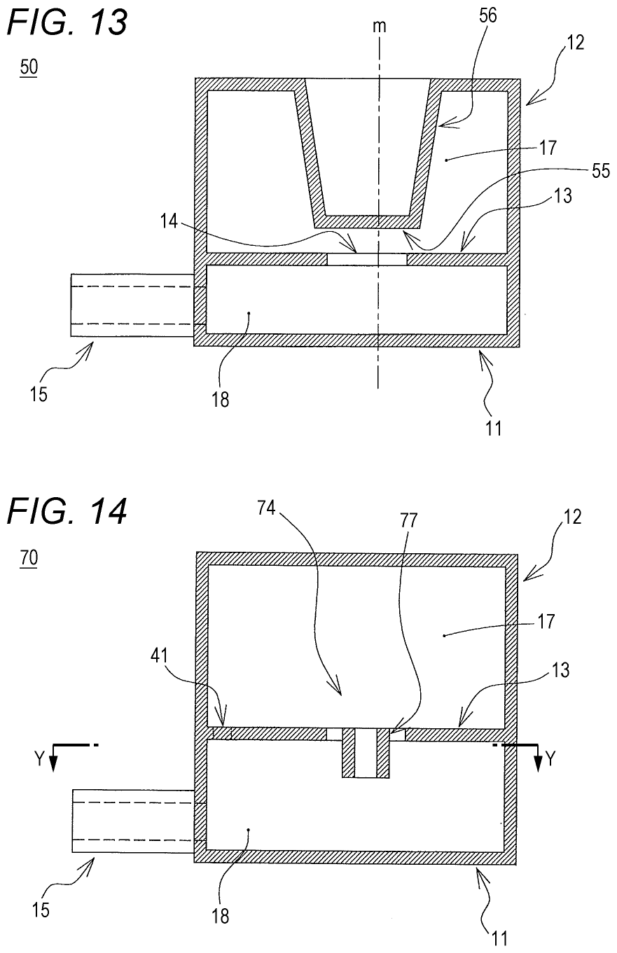

FIG. 13 illustrates a reservoir tank 50 of a fifth embodiment. FIG. 13 is a cross-sectional view taken along the line X-X, corresponding to FIGS. 2 and 7 of other embodiments. FIG. 13 illustrates a cross-sectional structure of the reservoir tank 50. The reservoir tank 50 of the fifth embodiment further includes a control surface 55 and a support portion 56 in the tank chamber 17 as compared with the reservoir tank 10 of the first embodiment. Other structures of the reservoir tank 50 are the same as those of the reservoir tank 10 of the first embodiment.

In the reservoir tank 50 of the fifth embodiment, the control surface 55 is provided inside the tank chamber 17 so as to face the communication hole 14 at a predetermined interval. The control surface 55 is provided to control the flow of the cooling fluid that flows from the gas-liquid separation chamber 18 into the tank chamber 17 through the communication hole 14 and flows upward of the tank chamber 17, to be a flow flowing in a lateral direction. The control surface 55 may be a plate or a block made of a material such as metal or resin that does not easily transmit liquid. The control surface 55 may be formed using a mesh material, a nonwoven fabric, a foam, or the like. In the fifth embodiment, the control surface 55 that does not easily transmit liquid is provided by using a plate material made of a thermoplastic resin.

The control surface 55 is preferably provided to cover the entire communication hole 14 so that the cooling fluid flowing into the tank chamber 17 from the communication hole 14 flows in the horizontal direction, that is, so that the control surface 55 is larger than the communication hole 14 when viewed in the vertical direction. The shape of the control surface 55 is not particularly limited. The shape of the control surface 55 is preferably a flat plate extending in a substantially horizontal direction as in the fifth embodiment.

The control surface 55 is supported by the support portion 56 on the upper case 12 constituting the tank chamber 17. The specific shape of the support portion 56 is not particularly limited as long as the control surface 55 can be properly supported. In the fifth embodiment, the support portion 56 is formed in a cylindrical shape. The outer periphery of the control surface 55 is supported by the support portion 56. Such a form is advantageous when the upper case 12 is injection-molded. The support portion 56 may support the control surface 55 on an upper surface (top surface) of the upper case 12 or may support the control surface 55 on a side surface (an outer surface) of the upper case 12. When a cap or a valve body is provided in the reservoir tank 50, the control surface 55 may be provided on the cap or the valve body. In this case, the support portion 56 may be omitted.

In the reservoir tank 50 of the fifth embodiment, the control surface 55 is provided inside the tank chamber 17 so as to face the communication hole 14 at the predetermined interval. Thus, even when the flow of the cooling fluid inside the gas-liquid separation chamber 18 is violent and the cooling fluid flows vigorously into the tank chamber 17 through the communication hole 14, the turbulent surface of the liquid inside the tank chamber 17 can be controlled, so that the bubbles are suppressed from being entrained in the cooling fluid. That is, the cooling fluid flowing into the tank chamber 17 through the communication hole 14 does not directly flow upward in the tank chamber 17 but is once diffused and flows in the lateral direction by the control surface 55. Therefore, since the flow of the cooling fluid flowing into the tank chamber 17 is diffused laterally and weakened, it is difficult to induce the turbulent surface of the liquid in the tank chamber 17. Therefore, in the reservoir tank 50 of the fifth embodiment, the effect of controlling the turbulent liquid surface of the cooling fluid in the tank chamber 17 is particularly enhanced.

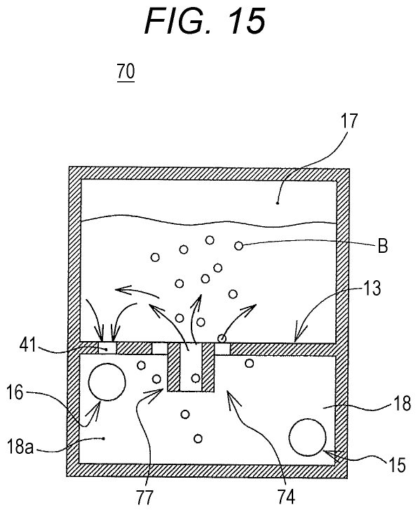

FIGS. 14 and 15 illustrate a reservoir tank 70 of a sixth embodiment. In the reservoir tank 70 of the sixth embodiment, a communication hole 74 is configured to include a pipe 77 as compared with the reservoir tank 40 of the fourth embodiment described with reference to FIGS. 10 to 12. Further, a value of height of the gas-liquid separation chamber 18 is set to be larger than any of diameters of the inflow pipe 15 and the discharge pipe 16. A position where the discharge pipe 16 is provided is set vertically higher than a position where the inflow pipe 15 is provided. Other structures of the reservoir tank 70 are the same as those of the reservoir tank 40 of the fourth embodiment. FIG. 14 is a cross-sectional view taken along the line X-X, corresponding to FIGS. 2 and 7 of other embodiments. FIG. 14 illustrates a vertical cross-sectional structure of the reservoir tank 70. FIG. 15 is a cross-sectional view taken along a line A-A (see FIG. 11) corresponding to FIG. 12 of the fourth embodiment.

In the reservoir tank 70 of the sixth embodiment, the communication hole 74 provided in the partition wall 13 is provided to include the pipe 77. That is, the communication hole 74 is configured such that a hollow tubular pipe 77 substantially vertically projects inwardly of the gas-liquid separation chamber 18 inside the through-hole provided in the plate-shaped partition wall 13. Although not essential, in the sixth embodiment, the pipe 77 is integrated with the partition wall 13 with a rib or the like. In the sixth embodiment, the pipe 77 is provided substantially at center of the through-hole. Instead of this, the pipe 77 may be provided at a peripheral portion of the through-hole. Or, the communication hole 74 may be provided such that the pipe 77 and the through-hole are arranged side by side.

With the structure of the communication hole 74, a portion of the through-hole between the partition wall 13 and the pipe 77 communicates a portion near the partition wall of the gas-liquid separation chamber 18 with the tank chamber 17. On the other hand, through a pipe line of the pipe 77, a portion central in height of the gas-liquid separation chamber 18 communicates with the tank chamber 17. The portion is downwardly distant from the partition wall 13.

As illustrated in FIG. 15, when the cooling fluid flows into the reservoir tank 70 of the sixth embodiment, the cooling fluid flows from the gas-liquid separation chamber 18 to the tank chamber 17 through the communication hole 74. Further, the secondary flow of the cooling fluid flowing from the tank chamber 17 to the gas-liquid separation chamber 18 through the suction hole 41 is generated. Then, from the through-hole of the communication hole 74, the cooling fluid containing many bubbles collected in an upper portion of the gas-liquid separation chamber 18 (near the partition wall 13) can be guided to the tank chamber 17. On the other hand, the cooling fluid can be guided to the tank chamber 17 by the pipe 77 from a position downwardly distant from the partition wall 13.

As described above, the reservoir tank 70 of the sixth embodiment includes the gas-liquid separation chamber 18 that separates the bubbles using both the centrifugal force and the gravity. In the reservoir tank 70 having such a structure, the bubbles gather at center of an arc-shaped flow and center of a vortex generated in the gas-liquid separation chamber 18, and move upward. However, when a bubble diameter is small, the bubbles hardly move upward, and fine bubbles are likely to remain in a tornado manner at the center of the arc-shaped flow and the center of the vortex in the gas-liquid separation chamber 18. When the pipe 77 is provided, the cooling fluid in which a lot of such fine bubbles are collected can be effectively sent into the tank chamber 17 from a position away from the partition wall 13. Therefore, the fine bubbles can be separated in the tank chamber 17. That is, when the communication hole 74 provided in the partition wall 13 is provided to include the pipe 77 as in the sixth embodiment, the cooling fluid can be guided from a portion in the gas-liquid separation chamber 18 where the air bubbles are likely to remain in the tank chamber 17. Therefore, the gas-liquid separation performance of the reservoir tank 70 can be further improved.

The reservoir tank according to the embodiment of the present disclosure may have other structures. For example, the reservoir tank may be provided with a removable cap. Through such a cap, the cooling fluid can be filled in the tank or the cooling fluid circuit. Further, a stay or a bracket or a boss member for attaching the reservoir tank to a vehicle body or the like may be integrated with the reservoir tank as necessary. Furthermore, the reservoir tank may be provided with a reinforcing structure such as a rib depending on a pressure resistance required for the reservoir tank.

The reservoir tank according to the embodiments of the present disclosure can be used in the cooling fluid circuit of the cooling system. The reservoir tank according to the embodiments of the present disclosure can separate the bubbles in the cooling fluid, and thus has a high industrial utility value.

Further, the reservoir tank according to the embodiments of the present disclosure may be the following first and second reservoir tanks.

The first reservoir tank is a reservoir tank provided in the cooling fluid circuit of the liquid-cooled cooling system, and includes: a tank chamber for storing a cooling fluid; a gas-liquid separation chamber provided adjacently below the tank chamber in a vertical direction; a partition wall for partitioning the tank chamber and the gas-liquid separation chamber; an inflow pipe for sending the cooling fluid into the reservoir tank; and a discharge pipe for discharging the cooling fluid from the reservoir tank. The inflow pipe and the discharge pipe are connected to the gas-liquid separation chamber, the gas-liquid separation chamber has a cylindrical outer peripheral wall, the cooling fluid sent in from the inflow pipe to the gas-liquid separation chamber flows along the cylindrical outer peripheral wall in a curved manner so as to rotate around a vertical axis, and is guided to the discharge pipe, the partition wall is provided with a communication hole communicating the tank chamber with the gas-liquid separation chamber, and the communication hole is provided at a position closer to a central axis of the cylindrical outer peripheral wall than to the cylindrical outer peripheral wall when viewed in the vertical direction.

The second reservoir tank is a reservoir tank provided in the cooling fluid circuit of the liquid-cooled cooling system, and includes: a tank chamber for storing a cooling fluid; a curved channel provided adjacently below the tank chamber in a vertical direction; a partition wall for partitioning the tank chamber and the curved channel; an inflow pipe for sending the cooling fluid into the reservoir tank; and a discharge pipe for discharging the cooling fluid from the reservoir tank. The inflow pipe and the discharge pipe are connected to the curved channel, the curved channel has a cylindrical outer peripheral wall, the cooling fluid sent in from the inflow pipe to the curved channel flows along the cylindrical outer peripheral wall in a curved manner so as to rotate around a vertical axis, and is guided to the discharge pipe, the partition wall is provided with a communication hole communicating the tank chamber with the curved channel, and the communication hole is provided on a radially inner peripheral side of a curve of the curved channel when viewed in the vertical direction.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A reservoir tank comprising:
a tank chamber for storing a cooling fluid;
a gas-liquid separation chamber provided adjacently below the tank chamber in a vertical direction;
a partition wall for partitioning the tank chamber and the gas-liquid separation chamber;
an inflow pipe for sending the cooling fluid into the reservoir tank; and
a discharge pipe for discharging the cooling fluid from the reservoir tank, wherein
the inflow pipe and the discharge pipe are connected to the gas-liquid separation chamber,
the gas-liquid separation chamber has a cylindrical outer peripheral wall,
the cooling fluid sent in from the inflow pipe to the gas-liquid separation chamber flows along the cylindrical outer peripheral wall in a curved manner so as to rotate around a vertical axis, and is guided to the discharge pipe,
the partition wall is provided with a communication hole communicating the tank chamber with the gas-liquid separation chamber, and
the communication hole is provided at a position closer to a central axis of the cylindrical outer peripheral wall than to the cylindrical outer peripheral wall when viewed in the vertical direction.

2. A reservoir tank comprising:
a tank chamber for storing a cooling fluid;
a curved channel provided adjacently below the tank chamber in a vertical direction;
a partition wall for partitioning the tank chamber and the curved channel;
an inflow pipe for sending the cooling fluid into the reservoir tank; and
a discharge pipe for discharging the cooling fluid from the reservoir tank, wherein
the inflow pipe and the discharge pipe are connected to the curved channel, the curved channel has a cylindrical outer peripheral wall,
the cooling fluid sent in from the inflow pipe to the curved channel flows along the cylindrical outer peripheral wall in a curved manner so as to rotate around a vertical axis, and is guided to the discharge pipe,
the partition wall is provided with a communication hole communicating the tank chamber with the curved channel, and
the communication hole is provided on a radially inner peripheral side of a curve of the curved channel when viewed in the vertical direction.

3. The reservoir tank according to claim 1, wherein the partition wall is provided to have a conical surface shape that goes vertically upward as it goes from an outer peripheral portion of the partition wall to the communication hole.

4. The reservoir tank according to claim 2, wherein the partition wall is provided to have a conical surface shape that goes vertically upward as it goes from an outer peripheral portion of the partition wall to the communication hole.

5. The reservoir tank according to claim 1, wherein a bottom surface of the gas-liquid separation chamber, which is located below in the vertical direction, is provided with a conical surface that goes vertically upward as it goes from the cylindrical outer peripheral wall to the central axis of the cylindrical outer peripheral wall.

6. The reservoir tank according to claim 2, wherein a bottom surface of the curved channel, which is located below in the vertical direction, is provided with a conical surface that goes vertically upward as it goes to the radially inner peripheral side of the curve of the curved channel.

7. The reservoir tank according to claim 1, wherein the communication hole is provided to be shifted downstream in a direction along a flow of the cooling fluid in the gas-liquid separation chamber.

8. The reservoir tank according to claim 2, wherein the communication hole is provided to be shifted downstream in a direction along a flow of the cooling fluid in the curved channel.

9. The reservoir tank according to claim 1, further comprising a suction hole that communicates the discharge pipe with the tank chamber.

10. The reservoir tank according to claim 2, further comprising a suction hole that communicates the discharge pipe with the tank chamber.
